(19) United States
(12) Patent Application Publication
(10) Pub. No.: US 2009/0219174 A1
(43) Pub. Date: Sep. 3, 2009

(54) Remote control method and remote control apparatus

(75) Inventors: Kazunori Kikuchi, Kanagawa (JP); Masahiro Nakano, Tokyo (JP); Yoshinori Satoh, Saitama (JP)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Sony Corporation, Tokyo (JP)

(21) Appl. No.: 12/380,443

(22) Filed: Feb. 27, 2009

(30) Foreign Application Priority Data
Feb. 29, 2008 (JP) P2008-049519

(51) Int. Cl. H03K 17/94; H04N 5/44

(52) U.S. Cl. 341/20; 348/734; 348/E05.096

(57) ABSTRACT

A remote control method is disclosed. The remote control method is used for a device under control which selects one of an information signal of the device under control and an information signal from at least one external device and reproduces the selected information signal.

### CROSS REFERENCES TO RELATED APPLICATIONS

The present invention contains subject matter related to Japanese Patent Application JP 2008-049519 filed in the Japanese Patent Office on Feb. 29, 2008, the entire contents of which being incorporated herein by reference.

### BACKGROUND OF THE INVENTION

1. Field of the Invention

The present invention relates to a remote control method and a remote control apparatus applied to remotely control, for example, a television receiver.

2. Description of the Related Art

External devices such as a recording device and a video signal reproduction device are connected to a television receiver and video signals as information received therefrom are displayed on a display section such as a liquid crystal display (LCD) monitor. If respective remote control apparatus (hereinafter referred to as remote controllers) are used for the television receiver and the external devices, the number of remote controllers increases and the user feels inconvenient.

A remote controller that can remotely control a plurality of devices such as a television receiver and a recording device is known as a so-called multi-remote controller. A multi-remote controller of a related art that is used to mainly control a television receiver and has a plurality of selection buttons with functions of input selection control and operation mode selection control has been proposed.

For example, a television selection button, a disc recorder (digital versatile disc (DVD) recorder, Blu-ray disc recorder, etc.) selection button, and a satellite tuner selection button are provided. When the television selection is pressed, an output of a tuner is selected and displayed on a display section, and the operation mode of the remote controller is set up to control the television receiver. Likewise, when the disc recorder selection button is pressed, a reproduction signal of the external disc recorder is input to the television receiver and the operation mode of the remote controller is set up to control the disc recorder. When the satellite tuner selection button is pressed, the similar operation is performed.

The operation mode of the remote controller is a mode in which control codes generated by the remote controller and remote control signals transmitted therefrom can control a predetermined device. A non-volatile memory of the remote controller has stored a table of control codes corresponding to buttons that are pressed. The tables correspond to categories of devices and device types. The categories represent concepts of Blu-ray disc recorder, DVD recorder, VTR, and so forth. The device types represent those that are identified by categories, manufacturer names, and device type numbers.

When the remote controller is packaged along with the television receiver, the remote controller can transmit control codes that the television receiver can interpret without necessity of performing a special setup operation for the remote controller. With respect to an external device such as a disc recorder, the remote controller is necessary to be set up to identify the manufacturer name (or device type). For example, a list of manufacturer codes (or an instruction manual) is prepared. With reference to the list, the remote controller is initially set up to control the external device. Specifically, control codes are set up with button operations of the remote controller. When the input selection and the operation mode selection are performed at the same time, the input selection state of the television receiver is matched with the operation mode selection state of the remote controller with a small number of buttons.

Such a remote controller is necessary to have the number of selection buttons corresponding to the maximum number of external devices connected to the television receiver, resulting in increasing the number of buttons of the remote controller. A related art reference that solves such a problem is described in Japanese Patent Application Laid-Open Publication No. 2007-13929, referred to as Patent Document 1. In this related art reference, one input selection button that selects an input of a device under control is disposed. When the selection button is operated, a remote control signal that designates an input to be selected is transmitted to the television receiver. The television receiver selects the designated input and transmits a status signal that represents the external device connected to the input of the television receiver to the remote controller. As a result, the operation mode of the remote controller becomes a mode in which it can control the external device designated by the status signal. In the television receiver, the relationship between input terminal numbers and connected external devices has been set up using a graphical user interface (GUI) on the screen of the television receiver and stored in a memory of the television receiver.

### SUMMARY OF THE INVENTION

In the remote controller described in the foregoing Patent Document 1, the relationship between the input terminals of the television receiver and the categories of the external devices was necessary to set up in advance. Since the remote control was necessary to be set up whenever connections of external devices were changed, the setup operations were bothersome. When one selection button was used, although the number of buttons was decreased, it was difficult to know the external devices connected to the television receiver. Although the remote controller described in Patent Document 1 discloses an example in which a plurality of self-illuminated buttons are provided, since TV, DVD, VTR, and AMP are marked with small letters on individual buttons, there is a problem that it is difficult to identify external devices connected to the television receiver. If letters are marked on individual buttons, there is a problem that no indication for a newly developed device exists.

In view of the foregoing, it would be desirable to provide a remote control method and a remote control apparatus that can solve problems involved in the foregoing prior art multi-remote controller.

According to an embodiment of the present invention, there is provided a remote control method for a device under control which selects one of an information signal of the device under control and an information signal from at least one external device and reproduces the selected information signal. Connection terminal identification information and device identification information of the external device are obtained from the external device and connection terminal identification information and device identification information of the external device are held when the external device is connected to the device under control. An inquiry is sent to the device under control and a reply is received therefrom to obtain the connection terminal identification information and the device identification information of the external device. The connection terminal identification information and the device identification information of the external device are registered to an input selection button. The external device represented by the device identification information is indicated corresponding to the input selection button. Transmitted to the device under control is an input selection signal which selects the connection terminal to which the indicated external device has been connected when the input selection button is operated. An operation mode is set up so as to transmit a remote control signal which controls the indicated external device to the external device.

It is preferred that using the number of input selection buttons which is equal to the number of connection terminals to which the external devices are connected.

It is preferred that a control code generation table which generates remote control signals which control the external device is provided.

It is preferred that a control code generation table which generates remote control signals which control the external device is obtained from the device under control.

It is preferred that the connection terminal identification information and the device identification information are automatically updated when connection information of the external device to the device under control is changed.

According to an embodiment of the present invention, there is provided a remote control apparatus for a device under control which selects one of an information signal of the device under control and an information signal from at least one external device and reproduces the selected information signal. The remote control apparatus includes an operation section, an indication section, a communication section, and a control section. The operation section has a plurality of buttons. The indication section is disposed in the vicinity of the operation section. The communication section bidirectionally communicates with the device under control. The control section inputs an operation signal from the operation section and controls the indication section and the control section. The device under control obtains connection terminal identification information and device identification information of the external device from the external device and holds the connection terminal identification information and device identification information of the external device when the external device is connected to the device under control. The control section sends an inquiry to the device under control and receives a reply therefrom to obtain the connection terminal identification information and the device identification information of the external device. The control section registers the obtained connection terminal identification information and the device identification information to an input selection button which is being operated and indicates the external device represented by the device identification information corresponding to the input selection button in the indication section. The control section transmits to the device under control an input selection signal which selects the connection terminal to which the indicated external device has been connected when the input selection button is operated and sets up an operation mode so as to transmit a remote control signal which controls the indicated external device to the external device.

According to embodiments of the present invention, when an external device is connected to the device under control, for example, a television receiver, since it obtains connection terminal identification information and device identification information of the external device and stores them, the user is not necessary to set up the relationship between the connection terminals and the external devices. In addition, since external devices are displayed corresponding to input selection buttons, the connected external devices can be easily identified and a desired device can be easily selected.

These and other objects, features and advantages of the present invention will become more apparent in light of the following detailed description of a best mode embodiment thereof, as illustrated in the accompanying drawings.

### BRIEF DESCRIPTION OF THE DRAWINGS

FIG. 1 is a schematic diagram describing an outline of an embodiment of the present invention;

FIG. 2 is a flow chart showing a process of this embodiment of the present invention;

FIG. 3 is a schematic diagram showing an example of a button arrangement of a remote controller according to this embodiment of the present invention;

FIG. 4A and FIG. 4B are block diagrams showing a structure of a communication device of an RF type remote controller according to an embodiment of the present invention; and

FIG. 5 is a schematic diagram describing another embodiment of the present invention.

### DETAILED DESCRIPTION OF THE PREFERRED EMBODIMENTS

Next, with reference to the accompanying drawings, embodiments of the present invention will be described. Although these embodiments that will be described in the following are preferred ones of the present invention and various technically preferably limitations are imposed thereto, it is appreciated that the scope of the present invention is not limited to these embodiments unless described that they impose the present invention.

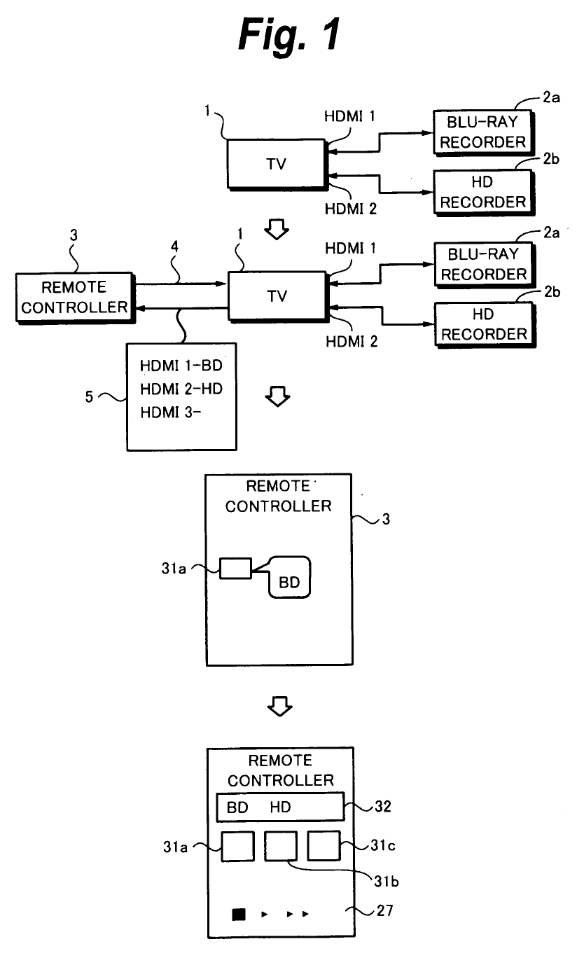

Next, with reference to FIG. 1, an embodiment of the present invention will be described. FIG. 1 describes a chronological flow of a process of an embodiment of the present invention. First, a Blu-ray disc (denoted by BD in the drawing) recorder 2a as an external device is connected to a connection terminal, for example, a high definition multimedia interface (HDMI 1) as a digital interface of a television receiver 1. A hard click (denoted by HD in the drawing) recorder 2 is connected to HDMI (HDMI 2).

HDMI is specifications for an interface of baseband video data, audio data, and control signals. When the Blu-ray disc recorder 2a starts a reproducing operation using the function of HDMI, the television receiver 1 can be controlled to automatically display a reproduced picture. In FIG. 1, paths of video data and audio data are omitted.

A control section (not shown) of the television receiver 1 can obtain respective identification information of the Blu-ray disc recorder 2a and the hard disk recorder 2b according to procedures defined in HDMI. The device identification information is identification information that can identify an external device. Specifically, the device identification information is a manufacturer name and a device type name. The device identification information may be information about a production year of the device.

The control section of the television receiver 1 stores information about the obtained connection terminal and the device identification information in a non-volatile memory. When external devices connected to the television receiver 1 are changed, the control section of the television receiver 1 automatically obtains the connection terminal identification information and the device identification information from a newly connected device and automatically updates the stored information in the latest state. In addition, when the state of the television receiver is updated, the control section of the television receiver 1 may automatically transmit updated connection terminal identification information and device identification information to the remote controller 3.

The television receiver 1 is provided with the remote controller 3. A communication section of the remote controller 3 bidirectionally communicates with the communication section of the television receiver 1, for example, according to a radio frequency (RF) system. In the radio type remote control method, the communication section of the remote controller 3 transmits an RF signal to a communication section mounted on the television receiver 1 to control an external device through HDMI as a digital interface.

The remote controller 3 transmits a connection inquiry 4 to the television receiver 1. The television receiver 1 sends back a reply about stored connection terminal identification information and device identification information to the remote controller 3. In other words, the television receiver 1 transmits information that denotes that the Blu-ray disc recorder 2a has been connected to the connection terminal HDMI 1 and the hard disk recorder 2b has been connected to the connection terminal HDMI 2 to the remote controller 3.

When the remote controller 3 receives the reply about the connection terminal identification information and the device identification information from the television receiver 1, the television receiver 1 stores them to the non-volatile memory and assigns respective external devices to a plurality of input selection buttons 31a, 31b, and 31c. For example, the remote controller 3 assigns the Blu-ray disc recorder 2a and the hard disk recorder 2b to the input selection button 31a and the input section button 31b, respectively. The remote controller 3 is provided with an indication section 32. Indications (BD, HD) of the assigned devices are indicated on the indication section 32. The indication section 32 is composed, for example, of an LCD and can indicate any characters. The indication section 32 may indicate an indication anytime or only when a predetermined button is operated.

External devices are not pre-assigned to the input selection buttons 31a, 31b, and 31c. The respective input selection buttons are assigned in the order, for example, of the reception of the connection terminal identification information and device identification information that have been transmitted as a reply 5.

The control section 10 has a read-only memory (ROM) that has stored tables of control codes (may be called remote control codes or preset codes) of a plurality of external devices (products). A table of control codes for device identification information corresponding to the pressed input selection button is set up. In this case, in the same manner as the related art reference, while the user refers to a list or the like, he or she may operate predetermined buttons of the remote controller 3 to set up tables for device types of the Blu-ray disc recorder 2a and the hard disk recorder 2b. Instead, the device identification information may contain device type information such that a table of control codes is selected according to the device type information.

Instead of storing tables of control codes, the reply 5 to the inquiry 4 from the remote controller 3 may contain control codes stored in each external device. For example, each external device may have stored a table of control codes and the table may be transmitted to the remote controller 3 through HDMI and the television receiver 1.

After the remote controller 3 has been initially set up in such a manner, if the user wants to select the Blu-ray disc recorder 2a as an input of the television receiver 1, he or she presses the input selection button 31a. This button operation causes the television receiver 1 to select the Blu-ray disc recorder 2a and the remote controller 3 to generate control codes that control the Blu-ray disc recorder 2a. In other words, the operation buttons disposed on the remote controller 3 are assigned to functions of the operation buttons of the Blu-ray disc recorder 2a.

For example, when a desired button of operation buttons 27 is pressed, the remote controller 3 transmits a control code corresponding to the pressed button to the television receiver 1. The television receiver 1 supplies the received control code to the Blu-ray disc recorder 2a through HDMI and the Blu-ray disc recorder 2a operates according to the operated button.

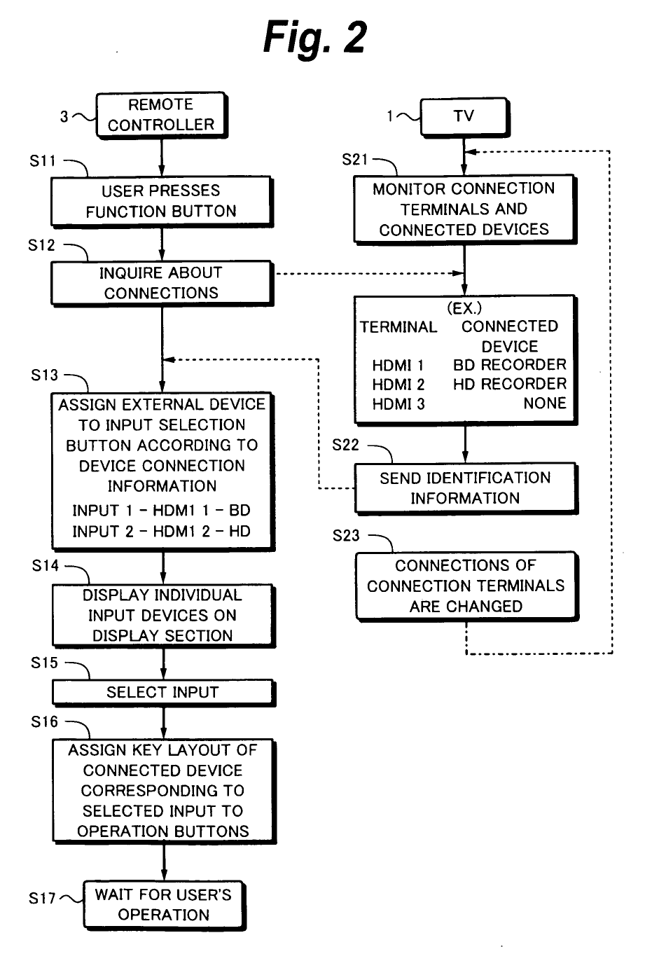

Next, with reference to FIG. 2, a flow of a process according to this embodiment of the present invention will be described. In FIG. 2, a process of the control section of the remote controller 3 and that of the television receiver 1 are separately illustrated.

The television receiver 1 monitors the relationship between connection terminals and connected devices (at step S21). The memory of the control section of the television receiver 1 has stored information about the relationship between latest connection terminals and connected devices (as a list). First, at step S11, a function button is pressed on the remote controller 3. The function button may be one specific button or be accomplished in combination of an input selection button and another button pressed simultaneously.

At step S12, the remote controller 3 inquires of the television receiver 1 about its connections. When the television receiver 1 is inquired, the television receiver 1 sends back a reply about stored information of the relationship of connection terminals and connected devices (identification information) to the remote controller 3 at step S22.

After the remote controller 3 has received the device information, the flow advances to step S13. At step S13, the remote controller 3 assigns the input selection buttons to external devices according to the device connection information. For example, the remote controller 3 assigns HDMI 1 and the Blu-ray disc recorder 2a to the input selection button 31a and HDMI 2 and the hard disk recorder 2b to the input selection button 31b.

At step S14, the individual input devices are indicated on the indication section 32. At step S15, when an input selection button is pressed, the input of the device corresponding to the input selection button is selected. At step S16, a key layout of a connected device corresponding to the pressed input selection button is set up for individual buttons of the remote controller 3. For example, when the input selection button 31a is pressed to select the Blu-ray disc recorder 2a, buttons of the remote controller 3 are set up to control the Blu-ray disc recorder 2a. In other words, the operation mode of the remote controller 3 becomes the Blu-ray disc recorder mode. Thereafter, the remote controller 3 waits for a user's operation (at step S16).

When the connections of the connection terminals of the television receiver 1 are changed at step S23, the flow returns to step S21. At step S21, the relationship between the connection terminals and the connected devices is automatically updated corresponding to the changed state.

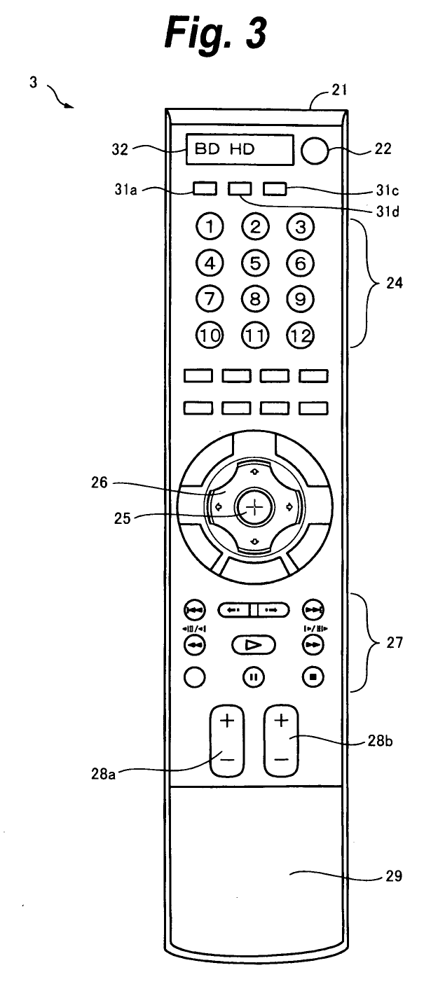

FIG. 3 shows an example of appearance of the structure of the remote controller 3. The remote controller 3 shown in FIG. 3 includes a plurality of operation buttons referred to as a button group disposed on the front of the housing; a transmission/reception section 21 that transmits and receive RF signals; and a shutter 29 that slidably opens and closes an inner button section having a plurality of operation buttons (not shown).

The button group includes a power on/off button 22, the input selection buttons 31a, 31b, 31c, a numeric button group 25, an enter button 25, a directional button 26, an operation button group 27 for playback, stop, etc. of an AV device, a sound volume up/down button 28a, and a channel up/down button 28b. The input selection buttons 31a, 31b, and 31c are used to cause a selection section to select an input picture displayed on the display section of the television receiver 1.

The indication section 32 is disposed in the vicinity of the input selection buttons. The indication section 32 indicates indications of devices assigned to the individual input selection buttons. For example, the indication section 32 indicates an indication (BD) that represents the Blu-ray disc recorder 2a corresponding to the input selection button 31a, an indication (HD) that represents the hard disk recorder 2b corresponding to the input selection button 31b. Although the input selection button 31c corresponds to a connection terminal, for example, an HDMI terminal, of the television receiver 1, since it has not been connected to a valid external device, the indication section 32 does not indicate an indication corresponding to the input selection button 31c.

In addition, the remote controller 3 is intended to control the television receiver 1. Thus, when any input selection button has not been pressed, the remote controller 3 generates control codes that control the television receiver 1. In other words, the operation mode of the remote controller 3 is the television receiver mode.

The buttons of the remote controller 3 can be categorized as those used to commonly control the television receiver 1 and the external devices (these buttons are referred to as common buttons), those dedicated for the television receiver 1 (hereinafter referred to as TV dedicated buttons), and those dedicated for the external devices (hereinafter referred to as external device dedicated buttons). The power on/off button 22, the numeric button group 24, the enter button 25, the directional button 26, the channel up/down button 28b, and so forth are categorized, for example, as the common buttons. On the other hand, the TV input selection buttons 31a, 31b, and 31c, the volume up/down button 28a, and so forth are categorized, for example, as the TV dedicated buttons. Moreover, the operation button group 27 for playback, stop, and so forth of the AV device are categorized, for example, as the external device dedicated buttons.

According to this embodiment of the present invention, the television receiver 1 and the remote controller 3 bidirectionally communicate with each other. Next, an example of the structure of a communication section that can bidirectionally communicate will be described.

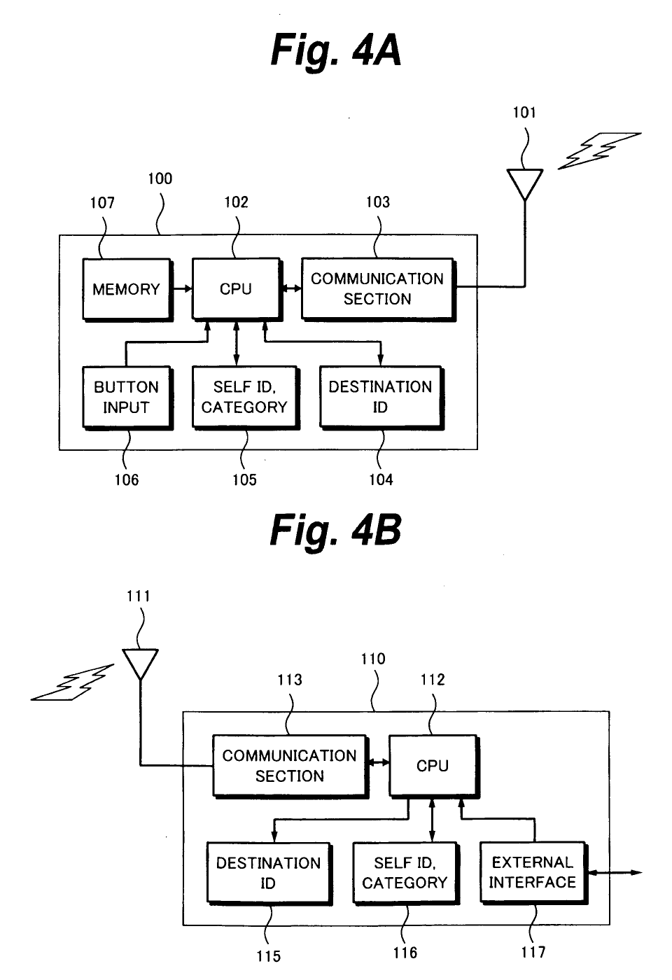

As shown in FIG. 4A, a remote controller communication device 100 corresponding to the communication section of the remote controller 3 has an antenna 101 that transmits and receives radio waves; a microprocessor (hereinafter referred to as the CPU) 102 as a control section that executes programs corresponding to a communication function, read and write operations for a storage medium, and various types of button inputs; a communication section 103 that radio communicates; a storage medium 104 that stores identification information ID of the pairing party; a storage medium 105 that stores an ID of the remote controller 3 itself and a category code of an electronic device with which the remote controller 3 initially pairs; a button input section 106 having buttons; and a memory 107 that generates control codes for remote control. The storage media 104, 105, and 107 are composed, for example, of respective writable non-volatile memories.

The CPU 102 includes a RAM and so forth and executes programs stored in a ROM and so forth to totally control each section of the communication unit 100. Identification information ID stored in the storage medium 104 is the ID of the television receiver 1 and the ID of the television receiver 1. An ID corresponding to a communication party that the CPU 102 sets up is used. In addition, the memory 107 has stored control codes of a plurality of manufacturers to allow control codes for remote control to be matched with those of a manufacturer name of a remote device.

As described above, when the function button is pressed, the CPU 102 transmits an inquiry to the television receiver 1 through the communication section 103 and the antenna 101. The CPU 102 receives a reply from the television receiver 1 through the antenna 101 and the communication section 103. The CPU 102 assigns the remote device to an input selection button according to the reply. The CPU 102 decides a control code according to the reply, generates the control code, and transmits a remote control signal (RF signal) containing the decided and generated control code to the remote device through the communication section 103.

As shown in FIG. 4B, a reception device that receives a remote control signal, for example, a communication device 110 corresponding to the communication section of the television receiver 1, has an antenna 111 that transmits and receives radio waves; a CPU 112 that executes programs corresponding to a communication function, read and write operations for a storage medium, and various types of button inputs; a communication section 113 that radio communicates; a storage medium 115 that stores identification information of the pairing party; a storage medium 116 that stores an ID of for example the television receiver itself and a category code (a code that represents a category of for example the television receiver); and an external interface 117 that interfaces with for example the television receiver. The storage medium 115 and the storage medium 116 are composed, for example, of respective non-volatile memories.

The CPU 112 totally controls each section of the reception device 110. The CPU 112 communicates with the control section of the television receiver 1 through the external interface 117. The CPU 112 controls the communication section 113 to transmit an RF signal containing information representing the selection state to the remote controller 3 through the antenna 111. In addition, the CPU 112 receives a self-addressed RF signal from the communication section 15 of the remote controller 3 and supplies the RF signal to the control section of the television receiver 1 through the external interface 117. The control section 10 performs an operation based on the received control code.

The communication section 103 of the communication unit 100 and the communication section 113 of the reception device 110 bidirectionally communicate with each other according to a predetermined radio communication system, for example, Institute of Electric and Electronic Engineers (IEEE) 802.15.4 and so forth. IEEE 802.15.4 is one of short range radio network standards, called Personal Area Network (PAN) or Wireless (W)PAN.

The communication rate of this standard is in the range from several 10 kbps to several 100 kbps and the communication distance is in the range from several 10 m to several 100 m. In addition, the communication is performed in the unit of a frame. One frame is composed of a payload (0 to 127 bytes) and a header (6 bytes). Thus, the maximum size of one frame is 133 bytes. In this communication system, one of a plurality of transmission and reception'systems can be used. In the remote control system, the simplest method in which the remote control apparatus transmits a command to the device under control and the remote control apparatus receives a reply from the device under control is used. Instead, more complicated transmission and reception methods than the foregoing methods may be used.

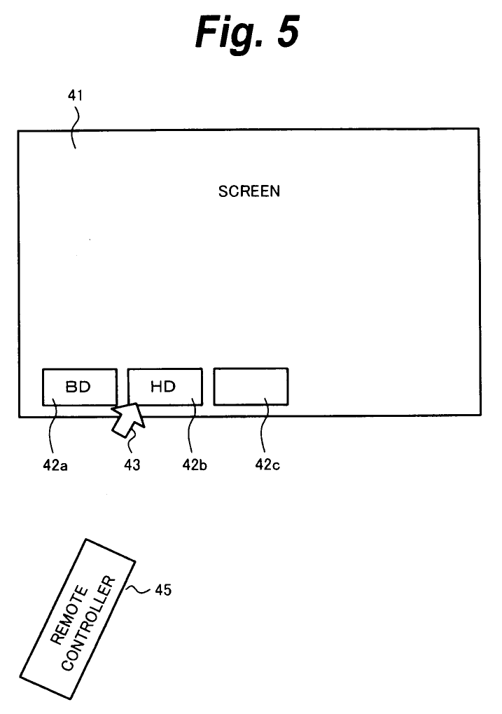

Instead, as shown in FIG. 5, a remote controller 45 having a pointer function may be used. A screen 41 of the television receiver 1 displays connection information as an input selection menu obtained by the television receiver 1 through a digital interface. For example, the screen 41 displays indicators 42a, 42b, and 42c that indicate device type names of connected external devices. The indicator 42a indicates an indication (BD) of the Blu-ray disc recorder 2a. The indicator 42b indicates an indication (HD) of the hard disk recorder 2b. The indicator 42c indicates no indication (blank) because a valid device is not connected.

The remote controller 45 causes a pointer 43 to move on the screen 41. With the remote controller 45, the pointer 43 is moved to a position corresponding to a desired external device and then the enter button (not shown) is pressed. For example, the pointer 43 is moved above the indicator 42b and then the enter button is pressed. This operation causes the television receiver 1 to send a reply about device identification information of the hard disk recorder as an external device to the remote controller 45. The remote controller 45 that has received the device identification information sets up an operation mode for the hard disk recorder 2b.

It should be understood by those skilled in the art that various modifications, combinations, sub-combinations and alternations may occur depending on design requirements and other factors insofar as they are within the scope of the appended claims or the equivalents thereof. For example, the number of external devices connected to the television receiver 1 may be two or more. In addition, the radio communication system may be other than IEEE 802.15.4 radio system.

What is claimed is:

1. A remote control method for a device under control which selects one of an information signal of the device under control and an information signal from at least one external device and reproduces the selected information signal, comprising steps of:
obtaining connection terminal identification information and device identification information of the external device from the external device and holding the connection terminal identification information and device identification information of the external device when the external device is connected to the device under control;
sending an inquiry to the device under control and receiving a reply therefrom to obtain the connection terminal identification information and the device identification information of the external device;
registering the obtained connection terminal identification information and the device identification information to an input selection button;
indicating the external device represented by the device identification information corresponding to the input selection button;
transmitting to the device under control an input selection signal which selects the connection terminal to which the indicated external device has been connected when the input selection button is operated; and
setting up an operation mode so as to transmit a remote control signal which controls the indicated external device to the external device.

2. The remote control method as set forth in claim 1, further comprising the step of:
using a number of input selection buttons which is equal to a number of connection terminals to which the external devices are connected.

3. The remote control method as set forth in claim 1, further comprising the step of:
providing a control code generation table which generates remote control signals which control the external device.

4. The remote control method as set forth in claim 1, further comprising the step of:
obtaining a control code generation table which generates remote control signals which control the external device from the device under control.

5. The remote control method as set forth in claim 1, further comprising the step of:
automatically updating the connection terminal identification information and the device identification information when connection information of the external device to the device under control is changed.

6. A remote control apparatus for a device under control which selects one of an information signal of the device under control and an information signal from at least one external device and reproduces the selected information signal, comprising:
an operation section which has a plurality of buttons;
an indication section disposed in a vicinity of the operation section;
a communication section which bidirectionally communicates with the device under control; and
a control section which inputs an operation signal from the operation section and controls the indication section and the control section,
wherein the device under control obtains connection terminal identification information and device identification information of the external device from the external device and holds the connection terminal identification information and device identification information of the external device when the external device is connected to the device under control,
wherein the control section sends an inquiry to the device under control and receives a reply therefrom to obtain the connection terminal identification information and the device identification information of the external device,
wherein the control section registers the obtained connection terminal identification information and the device identification information to an input selection button which is being operated and indicates the external device represented by the device identification information corresponding to the input selection button in the indication section, and
wherein the control section transmits to the device under control an input selection signal which selects the connection terminal to which the indicated external device has been connected when the input selection button is operated and sets up an operation mode so as to transmit a remote control signal which controls the indicated external device to the external device.
